(19) United States
(12) Patent Application Publication
(10) Pub. No.: US 2026/0036131 A1
(43) Pub. Date: Feb. 5, 2026

(54) FAN SPEED CONTROL SYSTEM, METHOD, AND DEVICE BASED ON OPTICAL SIGNAL TRANSMISSION, AND MEDIUM

(71) Applicant: Suzhou MetaBrain Intelligent Technology Co., Ltd., Suzhou, Jiangsu (CN)

(72) Inventor: Longting LI, Suzhou, Jiangsu (CN)

(21) Appl. No.: 19/139,439

(22) PCT Filed: Jun. 12, 2024
(86) PCT No.: PCT/CN2024/098743

§ 371 Date: Jun. 16, 2025

(30) Foreign Application Priority Data
Dec. 28, 2023 (CN) 202311834768.4

(51) Int. Cl. F04D 27/00; G01K 1/024; G08B 5/38; G08B 21/18; G08C 23/04; H05K 7/20

(52) U.S. Cl. CPC F04D 27/004; G01K 1/024; G08B 5/38; G08B 21/182; G08C 23/04; H05K 7/20727; H05K 7/20836

(57) ABSTRACT

Provided are a fan speed control system, method, and device based on optical signal transmission, and a medium. The system includes: first temperature-to-optical signal conversion modules, which are configured to sense temperature values at preset positions within a server and convert the temperature values into first optical signals; light-converging modules, which are configured to reflect and converge the first optical signals to form second optical signals directed toward the second temperature-to-optical signal conversion module; light-converging modules, which are correspondence with the first temperature-to-optical signal conversion modules; a second temperature-to-optical signal conversion module, which is disposed on one side where a fan is located within the server, and is configured to receive a plurality of second optical signals respectively corresponding to the plurality of preset positions within the server, and to control a rotational speed of the fan within the server based on the plurality of second optical signals.

### CROSS-REFERENCE TO RELATED APPLICATION

This application claims priority to Chinese Patent Application No. 202311834768.4, filed on Dec. 28, 2023 in China National Intellectual Property Administration and entitled “Fan Speed Control System, Method, and Device Based on Optical Signal Transmission, and Medium”, which is hereby incorporated by reference in its entirety.

### FIELD

The present application relates to the technical field of servers, and more particularly to a fan speed control system, method, and device based on optical signal transmission, and a medium.

### BACKGROUND

Excessive temperatures of server components might adversely affect the stability and reliability of a server. Therefore, cooling components such as fans are necessary to meet heat dissipation requirements. To balance application requirements on overall low power consumption and low noise of servers, intelligent control of fan speed is required.

In related technologies, multiple temperature monitoring units are utilized to monitor temperatures of crucial core components such as a printed circuit board (PCB), power chips, a central processing unit (CPU), and hard disk drives. The collected temperature data is transmitted via multiple inter-integrated circuit (I²C) buses to a baseboard management controller (BMC) chip. The BMC chip then comprehensively analyzes temperature characteristics to determine an appropriate fan rotational speed, and transmits rotational speed information to a fan. An internal digital control chip of the fan parses the rotational speed information to achieve intelligent fan rotational speed control.

The inventors have recognized that the above-mentioned intelligent fan rotational speed control solution suffers from issues such as a large number of temperature data transmission signals, long signal routing paths, and susceptibility to signal interference. Moreover, due to a large number of temperature sensing points and a singular sensing location of the BMC, an entire board requires a large number of communication lines, which occupy a substantial PCB routing space. In addition, to ensure the timeliness of temperature data processing, and due to a large number of data points and varying data evaluation criteria, BMC software becomes complex, leading to slower response speeds.

### SUMMARY

The present application provides a fan speed control system, method, and device based on optical signal transmission, and a medium, which might significantly reduce printed circuit board (PCB) routing and lower the design complexity of a baseboard management controller (BMC) within a server.

In a first aspect, the present application provides a fan speed control system based on optical signal transmission, which is applied to a server. The fan speed control system based on optical signal transmission includes: a plurality of first temperature-to-optical signal conversion modules, a plurality of light-converging modules, and a second temperature-to-optical signal conversion module.

The first temperature-to-optical signal conversion modules are configured to sense temperature values at preset positions within the server and convert the temperature values into first optical signals.

The light-converging modules are configured to reflect and converge the first optical signals to form second optical signals directed toward the second temperature-to-optical signal conversion module; and the light-converging modules are in one-to-one correspondence with the first temperature-to-optical signal conversion modules.

The second temperature-to-optical signal conversion module is disposed on one side where a fan is located within the server, and is configured to receive a plurality of second optical signals corresponding to the plurality of preset positions within the server, and to control a rotational speed of the fan within the server based on the plurality of second optical signals.

In some embodiments, each first temperature-to-optical signal conversion module includes a temperature sensing unit, a first control unit, and a light-emitting unit, wherein
the temperature sensing unit is configured to sense the temperature value at the preset position; and
the first control unit is configured to convert the temperature value into a current value and to control the light-emitting unit to emit a first optical signal at a first luminous intensity corresponding to the current value.

The second temperature-to-optical signal conversion module incudes an optical signal receiving unit and a second control unit, wherein
the optical signal receiving unit is configured to receive a plurality of second optical signals corresponding to the plurality of preset positions within the server; and
the second control unit is configured to generate a first control instruction carrying a target rotational speed based on the plurality of second optical signals, and to transmit the first control instruction to the fan within the server, whereby the fan within the server responds to the first control instruction, parses the target rotational speed from the first control instruction, and rotates at the target rotational speed.

In some embodiments, the first control unit and the second control unit are control chips.

In some embodiments, each light-converging module includes a reflector or a refractor.

In some embodiments, the reflector or refractor of the light-converging module is configured to reflect and converge the first optical signal to form a second optical signal directed toward the second temperature-to-optical signal conversion module.

In some embodiments, a position of the light-converging module is determined based on a relative positional relationship between the first temperature-to-optical signal conversion module and the second temperature-to-optical signal conversion module.

In some embodiments, the second control unit is configured to:
determine rotational speeds corresponding to second luminous intensities of the plurality of second optical signals;
determine a maximum rotational speed among the rotational speeds as the target rotational speed;
generate the first control instruction carrying the target rotational speed; and
transmit the first control instruction to the fan within the server.

In some embodiments, the first control unit is further configured to, when the temperature value exceeds a preset critical alarm threshold, control the light-emitting unit to emit a flashing third optical signal;
the light-converging module is further configured to reflect and converge the flashing third optical signal to form a flashing fourth optical signal directed toward the optical signal receiving unit;
the optical signal receiving unit is further configured to receive the flashing fourth optical signal; and
the second control unit is further configured to, when a flashing duration of the flashing fourth optical signal reaches a preset flashing duration, generate a second control instruction carrying a preset maximum rotational speed, and transmit the second control instruction to the fan within the server, whereby the fan within the server responds to the second control instruction, parses the preset maximum rotational speed from the second control instruction, and rotates at the preset maximum rotational speed.

In some embodiments, the first control unit is further configured to, when the temperature value falls below a preset temperature hysteresis threshold, control the light-emitting unit to stop emitting the flashing third optical signal and to switch to emitting the first optical signal.

In a second aspect, the present application further provides a fan speed control method based on optical signal transmission, which is applied to a first temperature-to-optical signal conversion module. The fan speed control method based on optical signal transmission includes:
converting a temperature value at a preset position within a server into a current value; and
controlling a light-emitting unit to emit a first optical signal at a first luminous intensity corresponding to the current value, to cause a light-converging module to reflect and converge the first optical signal to form a second optical signal directed toward a second temperature-to-optical signal conversion module, where the second temperature-to-optical signal conversion module receives a plurality of second optical signals respectively corresponding to a plurality of preset positions within the server, and generates a first control instruction carrying a target rotational speed based on the plurality of second optical signals, and the first control instruction is configured to instruct a fan within the server to rotate at the target rotational speed.

In some embodiments, the fan speed control method based on optical signal transmission further includes: controlling, when the temperature value exceeds a preset critical alarm threshold, the light-emitting unit to emit a flashing third optical signal, to cause the light-converging module to reflect and converge the flashing third optical signal to form a flashing fourth optical signal, where the second temperature-to-optical signal conversion module, when a flashing duration of the flashing fourth optical signal reaches a preset flashing duration, generates a second control instruction carrying a preset maximum rotational speed and transmits the second control instruction to the fan within the server, and the second control instruction is configured to instruct the fan within the server to rotate at the preset maximum rotational speed.

In some embodiments, the fan speed control method based on optical signal transmission further includes: controlling, when the temperature value falls below a preset temperature hysteresis threshold, the light-emitting unit to stop emitting the flashing third optical signal and switch to emitting the first optical signal.

In a third aspect, the present application further provides a fan speed control method based on optical signal transmission, which is applied to a second temperature-to-optical signal conversion module. The fan speed control method based on optical signal transmission includes:
generating a first control instruction carrying a target rotational speed based on a plurality of second optical signals, where the second optical signals are formed by reflecting and converging first optical signals through light-converging modules, the first optical signals are obtained by first temperature-to-optical signal conversion modules through conversion of temperature values at preset positions within a server, and the light-converging modules are in one-to-one correspondence with the first temperature-to-optical signal conversion modules; and
transmitting the first control instruction to a fan within the server, where the first control instruction is configured to instruct the fan within the server to rotate at the target rotational speed.

In some embodiments, the generating a first control instruction carrying a target rotational speed based on a plurality of second optical signals includes:
determining rotational speeds corresponding to second luminous intensities of the plurality of second optical signals;
determining a maximum rotational speed among the rotational speeds as the target rotational speed; and
generating the first control instruction carrying the target rotational speed.

In some embodiments, the fan speed control method based on optical signal transmission further includes:
generating, when a flashing duration of a flashing fourth optical signal reaches a preset flashing duration, a second control instruction carrying a preset maximum rotational speed, where the flashing fourth optical signal is formed by reflecting and converging a flashing third optical signal through the light-converging module, and the flashing third optical signal is emitted by the first temperature-to-optical signal conversion module when the temperature value exceeds a preset critical alarm threshold; and
transmitting the second control instruction to the fan within the server, where the second control instruction is configured to instruct the fan to rotate at the preset maximum rotational speed.

In a fourth aspect, the present application further provides a fan speed control device based on optical signal transmission, including:
a conversion module, configured to convert a temperature value at a preset position within a server into a current value; and
a control module, configured to control a light-emitting unit to emit a first optical signal at a first luminous intensity corresponding to the current value, to cause a light-converging module to reflect and converge the first optical signal to form a second optical signal directed toward a second temperature-to-optical signal conversion module, where the second temperature-to-optical signal conversion module receives a plurality of second optical signals respectively corresponding to a plurality of preset positions within the server, and generates a first control instruction carrying a target rotational speed based on the plurality of second optical signals, and the first control instruction is configured to instruct a fan within the server to rotate at the target rotational speed.

In a fifth aspect, the present application further provides a fan speed control device based on optical signal transmission, including:
a generation module, configured to generate a first control instruction carrying a target rotational speed based on a plurality of second optical signals, where the second optical signals are formed by reflecting and converging first optical signals through light-converging modules, the first optical signals are obtained by first temperature-to-optical signal conversion modules through conversion of temperature values at preset positions within a server, and the light-converging modules are in one-to-one correspondence with the first temperature-to-optical signal conversion modules; and
a transmission module, configured to transmit the first control instruction to a fan within the server, where the first control instruction is configured to instruct the fan to rotate at the target rotational speed.

In a sixth aspect, the present application further provides a first temperature-to-optical signal conversion module, including a temperature sensing unit, a first memory, and one or more first processors, where the first memory stores computer-readable instructions that, when executed by the one or more first processors, cause the one or more first processors to perform the steps of any of the fan speed control methods based on optical signal transmission described in the above-mentioned second aspect.

In a seventh aspect, the present application further provides a second temperature-to-optical signal conversion module, including an optical signal receiving unit, a second memory, and one or more second processors, where the second memory stores computer-readable instructions that, when executed by the one or more second processors, cause the one or more second processors to perform the steps of any of the fan speed control methods based on optical signal transmission described in the above-mentioned third aspect.

In an eighth aspect, the present application further provides a computer program product, including a computer program or instructions which, when executed by a processor, cause the processor to perform the steps of any of the fan speed control methods based on optical signal transmission described in the above-mentioned second or third aspect.

In a ninth aspect, the present application further provides one or more non-transitory computer-readable storage media having computer-readable instructions stored therein, where the computer-readable instructions, when executed by one or more processors, cause the one or more processors to perform the steps of any of the fan speed control methods based on optical signal transmission described in the above-mentioned second or third aspect.

### BRIEF DESCRIPTION OF THE DRAWINGS

In order to describe the technical solutions of the present application or in the existing technologies more clearly, drawings required to be used in the embodiments or the illustration of the existing technologies will be briefly introduced below. Apparently, the drawings in the illustration below are only some embodiments of the present application. Those ordinarily skilled in the art also might obtain other drawings according to the provided drawings without creative work.

FIG. 1 is a schematic structural diagram of a fan speed control system based on optical signal transmission according to one or more embodiments of the present application;

FIG. 2 is a schematic diagram of an operating principle of a light-converging module according to one or more embodiments of the present application;

FIG. 3 is a schematic diagram of a relationship between a luminous intensity and a fan rotational speed according to one or more embodiments of the present application;

FIG. 4 is a flowchart of a fan speed control method based on optical signal transmission according to one or more embodiments of the present application;

FIG. 5 is another flowchart of a fan speed control method based on optical signal transmission according to one or more embodiments of the present application;

FIG. 6 is a first schematic structural diagram of a fan speed control device based on optical signal transmission according to one or more embodiments of the present application;

FIG. 7 is a second schematic structural diagram of a fan speed control device based on optical signal transmission according to one or more embodiments of the present application;

FIG. 8 is a schematic structural diagram of a first temperature-to-optical signal conversion module according to one or more embodiments of the present application; and

FIG. 9 is a schematic structural diagram of a second temperature-to-optical signal conversion module according to one or more embodiments of the present application.

### DETAILED DESCRIPTION

In order to make objectives, technical solutions, and advantages of the embodiments of the present application clearer, the technical solutions in the embodiments of the present application will be described clearly and completely below with reference to the accompanying drawings. Apparently, the described embodiments are only part of the embodiments of the present application, rather than all of them. Based on the embodiments in the present application, all other embodiments obtained by those of ordinary skill in the art without creative efforts shall fall within the scope of protection of the present application.

Terms “first”, “second” and the like in the specification of the present application are adopted not to describe a specific sequence or order but to distinguish similar objects. It should be understood that these terms might be interchanged where appropriate, whereby the embodiments of the present application might be implemented in an order other than that illustrated or described herein. The objects distinguished by “first” and “second” generally belong to the same category and are not limited in number. For example, the “first object” may refer to one or more objects. In addition, the term “and/or” as used in the specification indicates at least one of the connected objects, and the character “/” generally denotes an “or” relationship between the associated objects.

Excessive temperatures of server components may lead to the following issues: 1) device instability or even failure; 2) accelerating the aging of electronic components and thus reducing a service life of electronic components; 3) negatively impacting device performance; and 4) reducing operating efficiency of the electronic components, resulting in low server processing speed and long response time. Therefore, a fan in a server plays a vital role in maintaining an appropriate temperature and ensuring the stability and reliability of the server.

Generally, a maximum fan rotational speed is determined based on a maximum heat dissipation requirement within a server system. For safety and reliability, if the fan continuously operates at its maximum rotational speed regardless of whether the server is under full load or light load, an internal temperature of the server system might indeed be maintained within acceptable limits.

However, if the fan continuously operates at a full speed, on one hand, unnecessary wear may occur due to a high fan rotational speed when internal components of the server are under light load, and on the other hand, operation at the maximum fan rotational speed generates significant noise, which substantially reduces a comfort level of a server environment during server operation. Therefore, fan speed control in servers is a critical aspect of server maintenance and management.

In related technologies, multiple temperature monitoring units are utilized to monitor temperatures of crucial core components such as a printed circuit board (PCB), power chips, a central processing unit (CPU), and hard disk drives. The collected temperature data is transmitted via multiple inter-integrated circuit (I²C) buses to a baseboard management controller (BMC) chip. The BMC chip then comprehensively analyzes temperature characteristics to determine an appropriate fan rotational speed, and transmits rotational speed information to a fan. An internal digital control chip of the fan parses rotational speed information to achieve intelligent fan rotational speed control.

However, the above-mentioned intelligent fan speed control solution suffers from issues such as a large number of temperature data transmission signals, long signal routing paths, and susceptibility to signal interference. Moreover, due to a large number of temperature sensing points and a singular sensing location of the BMC, an entire board requires a large number of communication lines, which occupy a substantial PCB routing space. In addition, to ensure the timeliness of temperature data processing, and due to a large number of data points and varying data evaluation criteria, BMC software becomes complex, leading to slower response speeds.

In view of this, embodiments of the present application provide a fan speed control system, method, and device based on optical signal transmission, and a medium. Detailed descriptions are provided below.

The following provides a detailed description of the fan speed control system based on optical signal transmission provided in the embodiments of the present application with reference to specific embodiments and application scenarios thereof.

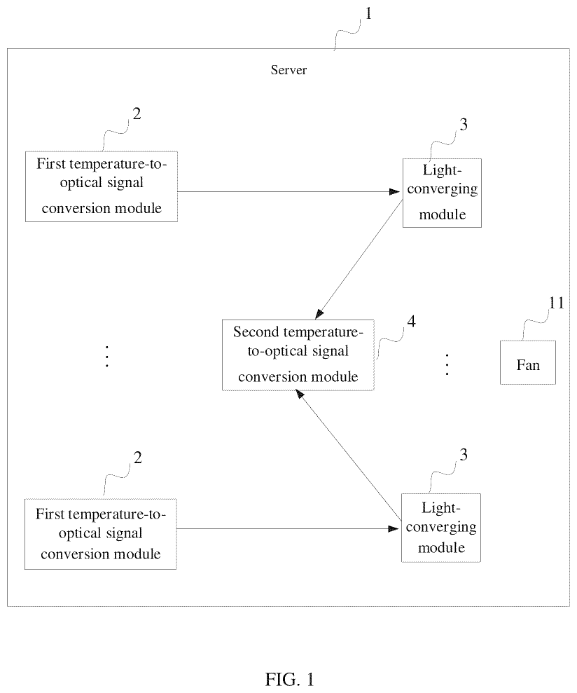

In a first aspect, please refer to FIG. 1, which is a schematic structural diagram of a fan speed control system based on optical signal transmission provided in some embodiments of the present application. As shown in FIG. 1, the system is applied to a server 1, and the system may include: a plurality of first temperature-to-optical signal conversion modules 2, a plurality of light-converging modules 3, and a second temperature-to-optical signal conversion module 4.

Crucial core components of the server 1 may include a PCB, power management chips, a CPU, a hard disk, and the like. A plurality of preset positions within the server 1 may correspond to positions near the crucial core components. Each crucial core component corresponds to a respective preset position, or a plurality of crucial core components correspond to a single preset position.

The first temperature-to-optical signal conversion modules 2 are configured to sense temperature values at preset positions within a server 1, convert the temperature values into first optical signals, and enable the temperature values to be transmitted via the first optical signals without requiring PCB routing for temperature data transmission.

The light-converging modules 3 are configured to reflect and converge the first optical signals to form second optical signals directed toward the second temperature-to-optical signal conversion module 4; and the light-converging modules 3 are in one-to-one correspondence with the first temperature-to-optical signal conversion modules 2.

In some embodiments, each light-converging module 3 includes a reflector or a refractor.

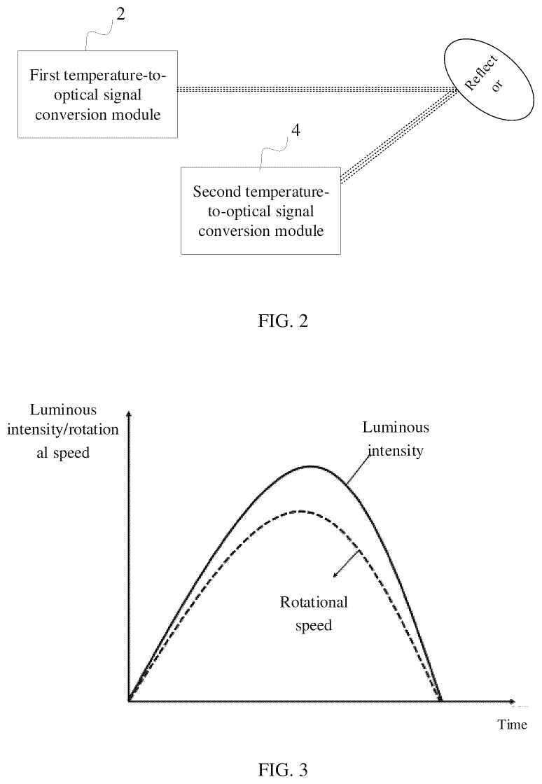

Exemplarily, a position of the light-converging module 3 is determined based on a relative positional relationship between the first temperature-to-optical signal conversion module 2 and the second temperature-to-optical signal conversion module 4. As shown in FIG. 2, the first temperature-to-optical signal conversion module 2 emits the first optical signal directed toward the light-converging module 3, and the light-converging module 3 reflects and converges the first optical signal to form the second optical signal directed toward the second temperature-to-optical signal conversion module 4. In this way, an optical scattering effect caused by spatial limitations within the server 1 might be reduced, thereby enabling high-accuracy transmission of luminous intensity in a complex environment within the server.

The second temperature-to-optical signal conversion module 4 is disposed on one side where a fan 11 is located within the server 1, and is configured to receive the plurality of second optical signals corresponding to the plurality of preset positions within the server 1, and to control a rotational speed of the fan 11 within the server 1 based on the plurality of second optical signals, and speed control of the fan 11 is thus achieved via optical signal transmission without involvement of a BMC chip.

A fan speed control system based on optical signal transmission provided in some embodiments of the present application includes: a plurality of first temperature-to-optical signal conversion modules, a plurality of light-converging modules, and a second temperature-to-optical signal conversion module, where the first temperature-to-optical signal conversion modules are configured to sense temperature values at preset positions within a server and convert the temperature values into first optical signals, and enable the temperature values to be transmitted via the first optical signals without requiring PCB routing for temperature data transmission; the light-converging modules are configured to reflect and converge the first optical signals to form second optical signals directed toward the second temperature-to-optical signal conversion module; the light-converging modules are in one-to-one correspondence with the first temperature-to-optical signal conversion modules and may achieve high-accuracy transmission of luminous intensity in a complex environment within the server; the second temperature-to-optical signal conversion module is disposed on one side where a fan is located within the server, and is configured to receive the plurality of second optical signals respectively corresponding to the plurality of preset positions within the server, and to control a rotational speed of the fan within the server based on the plurality of second optical signals; and fan speed control is thus achieved via optical signal transmission without involvement of a BMC chip. Therefore, the embodiment of the present application might significantly reduce PCB routing and lower the design complexity of a BMC within the server.

In some embodiments, each first temperature-to-optical signal conversion module 2 includes a temperature sensing unit, a first control unit, and a light-emitting unit, where
the temperature sensing unit is configured to sense a temperature value at a preset position.

In some embodiments, the temperature sensing unit may be a temperature sensor, which is capable of sensing a temperature value at a preset position in real time.

The first control unit is configured to convert the temperature value into a current value and to control the light-emitting unit to emit a first optical signal at a first luminous intensity corresponding to the current value.

In some embodiments, the first control unit may be a control chip, and the light-emitting unit may be a collimated light source. The control chip may adjust the current value based on the temperature value, adjust the first luminous intensity according to the current value, and then control the collimated light source to emit the first optical signal at the first luminous intensity. As the temperature value increases, the current value increases accordingly; and as the current value increases, the first luminous intensity also increases.

The second temperature-to-optical signal conversion module 4 includes an optical signal receiving unit and a second control unit, wherein the optical signal receiving unit is configured to receive a plurality of second optical signals respectively corresponding to the plurality of preset positions within the server 1.

In some embodiments, the optical signal receiving unit may be a photosensitive component, which is capable of receiving the plurality of second optical signals.

The second control unit is configured to generate a first control instruction carrying a target rotational speed based on the plurality of second optical signals, and to transmit the first control instruction to the fan 11 within the server 1, whereby the fan 11 within the server 1 responds to the first control instruction, parses the target rotational speed from the first control instruction, and rotates at the target rotational speed.

In some embodiments, the second control unit may be a control chip, which is configured to generate the first control instruction carrying the target rotational speed based on the plurality of second optical signals, and to transmit the first control instruction to the fan 11 within the server 1. The fan 11 within the server 1 responds to the first control instruction, parses the target rotational speed from the first control instruction, and rotates at the target rotational speed.

In some embodiments, the temperature sensing unit senses a temperature value at a preset position. The first control unit converts the temperature value into the current value and controls the light-emitting unit to emit the first optical signal at a first luminous intensity corresponding to the current value. In this way, the temperature value is transmitted via the first optical signal without involvement of PCB routing for temperature data transmission. The optical signal receiving unit receives the plurality of second optical signals respectively corresponding to the preset positions within the server. The second control unit generates the first control instruction carrying the target rotational speed based on the plurality of second optical signals, and transmits the first control instruction to the fan within the server. The first control instruction is configured to instruct the fan to rotate at the target rotational speed, and enables speed control of the fan through optical signal transmission without involvement of the BMC chip.

In some embodiments, the second control unit is configured to: determine rotational speeds corresponding to second luminous intensities of the plurality of second optical signals; determine a maximum rotational speed among the rotational speeds as the target rotational speed; generate a first control instruction carrying the target rotational speed; and transmit the first control instruction to the fan within the server.

Exemplarily, as shown in FIG. 3, as the temperature value at each preset position increases, the second light intensities of the plurality of second optical signals increase and the target rotational speed increases accordingly. After the fan 11 operates at the target rotational speed for a period of time, the temperature value at each preset position decreases, the second light intensities of the plurality of second optical signals are reduced, and the target rotational speed is accordingly lowered.

In some embodiments, a maximum rotational speed among the rotational speeds respectively corresponding to the second light intensities of the plurality of second optical signals is selected as the target rotational speed of the fan within the server, thereby achieving rapid heat dissipation for critical core components within the server.

In some embodiments, the first control unit is further configured to, when the temperature value exceeds a preset critical alarm threshold, control the light-emitting unit to emit a flashing third optical signal.

In some embodiments, due to light scattering effects, potential errors in signal transmission, delays in signal parsing, and possible system faults, the fan speed control may be delayed, and temperature control may be inaccurate, thereby posing a risk of a rapid temperature rise in critical core components.

When the temperature value exceeds the preset critical alarm threshold, it indicates that the temperature has reached a relatively high level. For example, if a maximum allowable temperature of a critical core component is 125° C., and the temperature value exceeds the preset critical alarm threshold of 105° C., any further temperature rise may cause the critical core component to fail, compromising its reliability. In such a case, rapid heat dissipation needs to be provided for the critical core component. The first control unit controls the light-emitting unit to emit a flashing third optical signal, which serves as a high-temperature warning signal.

The light-converging module 3 is further configured to reflect and converge the flashing third optical signal to form a flashing fourth optical signal directed toward the optical signal receiving unit.

In some embodiments, the flashing third optical signal is reflected and converged by the light-converging module 3 to form the flashing fourth optical signal directed toward the optical signal receiving unit.

The optical signal receiving unit is further configured to receive the flashing fourth optical signal.

The second control unit is further configured to, when a flashing duration of the flashing fourth optical signal reaches a preset flashing duration, generate a second control instruction carrying a preset maximum rotational speed, and transmit the second control instruction to the fan 11 within the server 1, whereby the fan 11 within the server 1 responds to the second control instruction, parses the preset maximum rotational speed from the second control instruction, and rotates at the preset maximum rotational speed.

In some embodiments, the preset flashing duration may be 5 seconds. When the flashing duration of the flashing fourth optical signal is detected to last for 5 seconds, the second control instruction carrying the preset maximum rotational speed is generated and transmitted to the fan 11 within the server 1. The second control instruction is configured to instruct the fan 11 within the server 1 to rotate at the preset maximum rotational speed, thereby rapidly dissipating heat from the critical core components.

In some embodiments, boundary control of harsh temperature environments inside the server might be achieved by utilizing an easily recognizable characteristic of optical flashing.

In some embodiments, the first control unit is further configured to, when the temperature value falls below a preset temperature hysteresis threshold, control the light-emitting unit to stop emitting the flashing third optical signal and to switch to emitting the first optical signal.

In some embodiments, the preset temperature hysteresis value may be 20°. When the temperature value exceeds the preset critical alarm threshold of 105°, a flashing optical signal is emitted. When detecting that the temperature value has dropped by 20°, i.e., falls below 85°, the light-emitting unit is controlled to stop emitting the flashing third optical signal and switch to emitting the first optical signal, thereby resuming an original control strategy instead of continuously maintaining the preset maximum rotational speed.

In some embodiments, when detecting that the temperature value falls below the preset temperature hysteresis value, the light-emitting unit is controlled to stop emitting the flashing third optical signal and to switch to emitting the first optical signal; and in this way, problems of high energy consumption and excessive noise caused by the fan within the server continuously operating at the preset maximum rotational speed might be avoided.

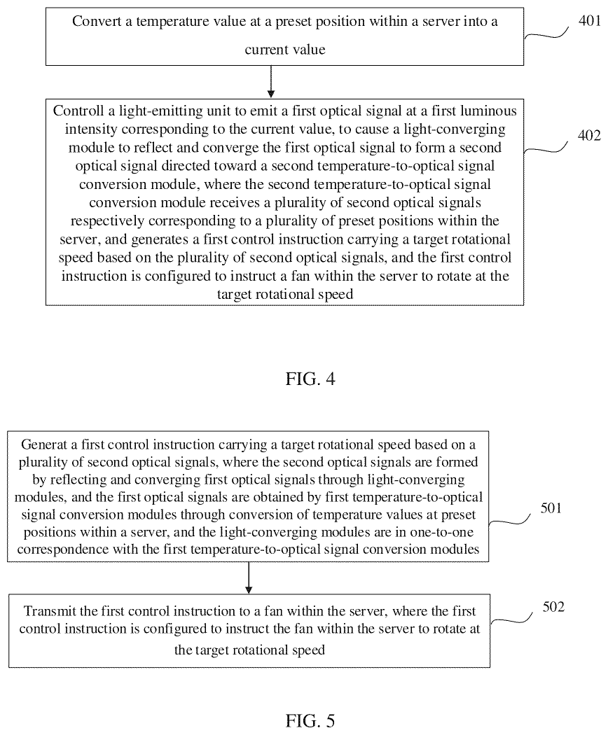

In a second aspect, please refer to FIG. 4, which is a flowchart of a fan speed control method based on optical signal transmission provided in some embodiments of the present application. The method is applied to a first temperature-to-optical signal conversion module. As shown in FIG. 4, the method may include the following steps:

Step 401: Converting a temperature value at a preset position within a server into a current value.

Step 402: Controlling a light-emitting unit to emit a first optical signal at a first luminous intensity corresponding to the current value, to cause a light-converging module to reflect and converge the first optical signal to form a second optical signal directed toward a second temperature-to-optical signal conversion module, where the second temperature-to-optical signal conversion module receives a plurality of second optical signals respectively corresponding to a plurality of preset positions within the server, and generates a first control instruction carrying a target rotational speed based on the plurality of second optical signals, and the first control instruction is configured to instruct a fan within the server to rotate at the target rotational speed.

In some embodiments, the temperature value at the preset position within the server is converted into the current value and the light-emitting unit is controlled to emit the first optical signal at a first luminous intensity corresponding to the current value. In this way, the temperature value is transmitted via the first optical signal without involvement of PCB routing for temperature data transmission. The light-converging module reflects and converges the first optical signal to form the second optical signal directed toward the second temperature-to-optical signal conversion module. In this way, high-accuracy transmission of luminous intensity in a complex environment within the server might be achieved. The second temperature-to-optical signal conversion module receives the plurality of second optical signals corresponding to the plurality of preset positions within the server, and generates the first control instruction carrying the target rotational speed based on the plurality of second optical signals. The first control instruction is configured to instruct the fan to rotate at the target rotational speed, and enables speed control of the fan through optical signal transmission without involvement of the BMC chip. Therefore, the embodiment of the present application might significantly reduce PCB routing and lower the design complexity of a BMC within the server.

In some embodiments, the fan speed control method based on optical signal transmission further includes: controlling, when the temperature value exceeds a preset critical alarm threshold, the light-emitting unit to emit a flashing third optical signal, to cause the light-converging module to reflect and converge the flashing third optical signal to form a flashing fourth optical signal, where the second temperature-to-optical signal conversion module, when a flashing duration of the flashing fourth optical signal reaches a preset flashing duration, generates a second control instruction carrying a preset maximum rotational speed and transmits the second control instruction to the fan within the server, and the second control instruction is configured to instruct the fan within the server to rotate at the preset maximum rotational speed.

In some embodiments, boundary control of harsh temperature environments inside the server might be achieved by utilizing an easily recognizable characteristic of optical flashing.

In some embodiments, the fan speed control method based on optical signal transmission further includes: controlling, when the temperature value falls below a preset temperature hysteresis threshold, the light-emitting unit to stop emitting the flashing third optical signal and switch to emitting the first optical signal.

In some embodiments, when detecting that the temperature value falls below the preset temperature hysteresis value, the light-emitting unit is controlled to stop emitting the flashing third optical signal and to switch to emitting the first optical signal; and in this way, problems of high energy consumption and excessive noise caused by the fan within the server continuously operating at the preset maximum rotational speed might be avoided.

In a third aspect, please refer to FIG. 5, which is another flowchart of a fan speed control method based on optical signal transmission provided in some embodiments of the present application. The fan speed control method based on optical signal transmission is applied to a second temperature-to-optical signal conversion module. As shown in FIG. 5, the fan speed control method based on optical signal transmission includes:

Step 501: Generating a first control instruction carrying a target rotational speed based on a plurality of second optical signals, where the second optical signals are formed by reflecting and converging first optical signals through light-converging modules, and the first optical signals are obtained by first temperature-to-optical signal conversion modules through conversion of temperature values at preset positions within a server, and the light-converging modules are in one-to-one correspondence with the first temperature-to-optical signal conversion modules.

Step 502: Transmitting the first control instruction to a fan within the server, where the first control instruction is configured to instruct the fan within the server to rotate at the target rotational speed.

In some embodiments, the first temperature-to-optical signal conversion modules convert the temperature values at the preset positions within the server into first optical signals, and enable the temperature values to be transmitted via the first optical signals without requiring PCB routing for temperature data transmission. The light-converging module reflects and converges the first optical signal to form the second optical signal. In this way, high-accuracy transmission of luminous intensity in a complex environment within the server might be achieved. The first control instruction carrying the target rotational speed is generated based on the plurality of second optical signals, and the first control instruction is transmitted to the fan within the server. The first control instruction is configured to instruct the fan within the server to rotate at the target rotational speed, and enables speed control of the fan through optical signal transmission without involvement of a BMC chip. Therefore, the embodiment of the present application might significantly reduce PCB routing and lower the design complexity of a BMC within the server.

In some embodiments, the Step 501 includes the following steps.

Step 5011: Determining rotational speeds corresponding to second luminous intensities of second optical signals;

Step 5012: Determining a maximum rotational speed among the rotational speeds as the target rotational speed; and

Step 5013: Generating the first control instruction carrying the target rotational speed.

In some embodiments, a maximum rotational speed among the rotational speeds respectively corresponding to the second light intensities of the plurality of second optical signals is selected as the target rotational speed of the fan within the server, thereby achieving rapid heat dissipation for critical core components within the server.

In some embodiments, the fan speed control method based on optical signal transmission further includes:
generating, when a flashing duration of a flashing fourth optical signal reaches a preset flashing duration, a second control instruction carrying a preset maximum rotational speed, where the flashing fourth optical signal is formed by reflecting and converging a flashing third optical signal through the light-converging module, and the flashing third optical signal is emitted by the first temperature-to-optical signal conversion module when the temperature value exceeds a preset critical alarm threshold; and
transmitting the second control instruction to the fan within the server, where the second control instruction is configured to instruct the fan to rotate at the preset maximum rotational speed.

In some embodiments, boundary control of harsh temperature environments inside the server might be achieved by utilizing an easily recognizable characteristic of optical flashing.

It should be noted that the fan speed control method based on optical signal transmission provided in some embodiments of the present application may be implemented by a fan speed control device based on optical signal transmission, or by a control module within the fan speed control device for implementing the fan speed control method based on optical signal transmission. In some embodiments of the present application, an example in which the fan speed control device based on optical signal transmission performs the fan speed control method based on optical signal transmission is taken to illustrate the fan speed control device based on optical signal transmission provided in some embodiments of the present application.

It should be noted that in some embodiments of the present application, the above-mentioned fan speed control methods based on optical signal transmission as shown in the method accompanying drawings are exemplarily described with reference to individual accompanying drawings in some embodiments of the present application. In specific implementations, the fan speed control methods based on optical signal transmission as illustrated in the above accompanying drawings may also be implemented in conjunction with any other compatible accompanying drawings exemplified in the above-mentioned embodiments, and detailed descriptions are repeated herein.

The fan speed control device based on optical signal transmission provided in this application will be described below. The description below might be referenced with the fan speed control method based on optical signal transmission described above.

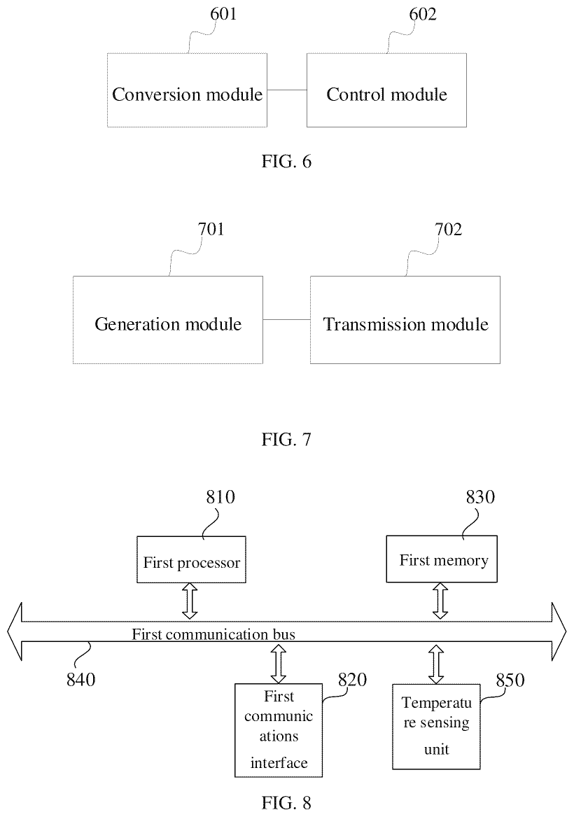

In a fourth aspect, please refer to FIG. 6, which is a first schematic structural diagram of a fan speed control device based on optical signal transmission provided in some embodiments of the present application. As shown in FIG. 6,
a conversion module 601 is configured to convert a temperature value at a preset position within a server into a current value; and
a control module 602 is configured to control a light-emitting unit to emit a first optical signal at a first light intensity corresponding to the current value, to cause a light-converging module to reflect and converge the first optical signal to form a second optical signal directed toward a second temperature-to-optical signal conversion module, where the second temperature-to-optical signal conversion module receives a plurality of second optical signals respectively corresponding to a plurality of preset positions within the server, and generates a first control instruction carrying a target rotational speed based on the plurality of second optical signals, and the first control instruction is configured to instruct a fan within the server to rotate at the target rotational speed.

In some embodiments, the control module 602 is further configured to, when the temperature value exceeds a preset critical alarm threshold, control the light-emitting unit to emit a flashing third optical signal, to cause the light-converging module to reflect and converge the flashing third optical signal to form a flashing fourth optical signal, where the second temperature-to-optical signal conversion module, when a flashing duration of the flashing fourth optical signal reaches a preset flashing duration, generates a second control instruction carrying a preset maximum rotational speed and transmits the second control instruction to the fan within the server, and the second control instruction is configured to instruct the fan within the server to rotate at the preset maximum rotational speed.

In some embodiments, the control module 602 is further configured to, when the temperature value falls below a preset temperature hysteresis threshold, control the light-emitting unit to stop emitting the flashing third optical signal and to switch to emitting the first optical signals.

In a fifth aspect, please refer to FIG. 7, which is a second schematic structural diagram of a fan speed control device based on optical signal transmission provided in some embodiments of the present application. As shown in FIG. 7,
a generation module 701 is configured to generate a first control instruction carrying a target rotational speed based on a plurality of second optical signals, where the second optical signals are formed by reflecting and converging first optical signals through light-converging modules, the first optical signals are obtained by first temperature-to-optical signal conversion modules through conversion of temperature values at preset positions within a server, and the light-converging modules are in one-to-one correspondence with the first temperature-to-optical signal conversion modules; and
a transmission module 702 is configured to transmit the first control instruction to a fan within a server, where the first control instruction is configured to instruct the fan within the server to rotate at the target rotational speed.

In some embodiments, the generation module 701 is configured to:
determine rotational speeds corresponding to second luminous intensities of second optical signals;
determine a maximum rotational speed among the rotational speeds as the target rotational speed; and
generate the first control instruction carrying the target rotational speed.

In some embodiments, the generation module 701 is further configured to, when a flashing duration of a flashing fourth optical signal reaches a preset flashing duration, generate a second control instruction carrying a preset maximum rotational speed, where the flashing fourth optical signal is formed by reflecting and converging a flashing third optical signal through the light-converging module, and the flashing third optical signal is emitted by the first temperature-to-optical signal conversion module when the temperature value exceeds a preset critical alarm threshold; and
the transmission module 702 is further configured to transmit the second control instruction to the fan within the server, where the second control instruction is configured to instruct the fan to rotate at the preset maximum rotational speed.

In a sixth aspect, the present application further provides a first temperature-to-optical signal conversion module, including a temperature sensing unit, a first memory, and one or more first processors, where the first memory stores computer-readable instructions that, when executed by the one or more first processors, cause the one or more first processors to perform the steps of the fan speed control methods provided in any of the embodiments described in the above-mentioned second aspect.

FIG. 8 is a schematic diagram of a physical structure of a first temperature-to-optical signal conversion module. As shown in FIG. 8, the first temperature-to-optical signal conversion module may include: a first processor 810, a first communications interface 820, a first memory 830, a first communication bus 840, and a temperature sensing unit 850, where the first processor 810, the first communications interface 820, and the first memory 830 communicate with one another via the first communication bus 840. The first processor 810 may call logic instructions stored in the first memory 830 to implement the fan speed control method based on optical signal transmission. The method includes: converting a temperature value at a preset position within a server into a current value; and controlling a light-emitting unit to emit a first optical signal at a first luminous intensity corresponding to the current value, to cause a light-converging module to reflect and converge the first optical signal to form a second optical signal directed toward a second temperature-to-optical signal conversion module, where the second temperature-to-optical signal conversion module receives a plurality of second optical signals respectively corresponding to a plurality of preset positions within the server, and generates a first control instruction carrying a target rotational speed based on the plurality of second optical signals, and the first control instruction is configured to instruct a fan within the server to rotate at the target rotational speed.

In a seventh aspect, the present application further provides a second temperature-to-optical signal conversion module, including an optical signal receiving unit, a second memory, and one or more second processors, where the second memory stores computer-readable instructions that, when executed by the one or more second processors, cause the one or more second processors to perform the steps of the fan speed control methods provided in any of the embodiments described in the above-mentioned third aspect.

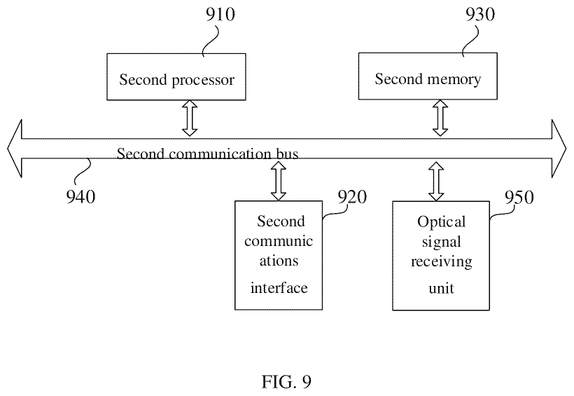

FIG. 9 is a schematic diagram of a physical structure of a second temperature-to-optical signal conversion module. As shown in FIG. 9, the second temperature-to-optical signal conversion module may include: a second processor 910, a second communications interface 920, a second memory 930, a second communication bus 940, and an optical signal receiving unit 950, where the second processor 910, the second communications interface 920, and the second memory 930 communicate with one another via the second communication bus 940. The second processor 910 may call logic instructions stored in the second memory 930 to implement the fan speed control method based on optical signal transmission. The method includes: generating a first control instruction carrying a target rotational speed based on a plurality of second optical signals, where the second optical signals are formed by reflecting and converging first optical signals through light-converging modules, the first optical signals are obtained by first temperature-to-optical signal conversion modules through conversion of temperature values at preset positions within a server, and the light-converging modules are in one-to-one correspondence with the first temperature-to-optical signal conversion modules; and transmitting the first control instruction to a fan within the server, where the first control instruction is configured to instruct the fan within the server to rotate at the target rotational speed.

In addition, the logic instructions stored in the above-mentioned first memory 830 or second memory 930 may be implemented in the form of software functional modules and, when sold or used as standalone products, may be stored in a computer-readable storage medium. Based on such an understanding, the technical solutions of the present application substantially or parts making contributions to the existing technologies or part of the technical solutions may be embodied in form of software products, and the computer software product is stored in a storage medium, including a plurality of instructions configured to enable a computer device (which may be a personal computer, a server, a network device or the like) to implement all or part of the steps of the method in each embodiment of the present application. The above-mentioned storage medium includes: various media capable of storing program codes such as a U disk, a read-only memory (ROM), a random access memory (RAM), a magnetic disk or an optical disk.

In an eighth aspect, the present application further provides a computer program product, which includes a computer program stored on a computer-readable storage medium. The computer program includes program instructions which, when executed by a computer, cause the computer to implement the fan speed control method based on optical signal transmission provided in any one of the embodiments described in the second or third aspects. Detailed descriptions are not repeated herein.

In a ninth aspect, the present application further provides one or more non-transitory computer-readable storage media having computer-readable instructions stored therein. The computer-readable instructions, when executed by the one or more processors, cause the one or more processors to perform the steps of the method provided in any one of the embodiments described in the above-mentioned second or third aspects. Detailed descriptions are not repeated herein.

The embodiments of the device described above are merely illustrative. The units described as separate components may or may not be physically separated, and components shown as units may or may not be physical entities. They may be located in one place or distributed across multiple network units. Part or all of the modules may be selected to achieve the purpose of the solutions of the embodiments according to a practical requirement. A person of ordinary skill in the art may understand and implement without involving any inventive effort.

From the above descriptions about the implementations, those skilled in the art may clearly know that the implementations may be implemented in a manner of combining software and a necessary universal hardware platform, and of course, may also be implemented through hardware. Based on such an understanding, the technical solutions may be embodied in form of software products, and the computer software product is stored in a storage medium, such as a Read-Only Memory (ROM)/Random Access Memory (RAM), magnetic disks, optical disks, etc., including a plurality of instructions configured to enable a computer device (which may be a personal computer, a server, a network device or the like) to implement all or part of the method in each embodiment of the present application.

Finally, it should be noted that the above-mentioned embodiments are merely illustrative of the technical solution of the present application, and do not limit same; while the present application has been described in detail with reference to the foregoing embodiments, those skilled in the art will appreciate that: the technical solutions disclosed in the above-mentioned embodiments might still be modified or some of the technical characteristics might be replaced by equivalents; however, these modifications or substitutions do not depart from the spirit and scope of the technical solutions of the embodiments of the present application in nature.

1. A fan speed control system based on optical signal transmission, being applied to a server and comprising: a plurality of first temperature-to-optical signal conversion modules, a plurality of light-converging modules, and a second temperature-to-optical signal conversion module, wherein
the first temperature-to-optical signal conversion modules are configured to sense temperature values at preset positions within the server and convert the temperature values into first optical signals;
the light-converging modules are configured to reflect and converge the first optical signals to form second optical signals directed toward the second temperature-to-optical signal conversion module; the light-converging modules are in one-to-one correspondence with the first temperature-to-optical signal conversion modules; and
the second temperature-to-optical signal conversion module is disposed on one side where a fan is located within the server, and is configured to receive a plurality of second optical signals respectively corresponding to the preset positions within the server, and to control a rotational speed of the fan within the server based on the plurality of second optical signals.

2. The fan speed control system based on optical signal transmission according to claim 1, wherein each of the first temperature-to-optical signal conversion modules comprises a temperature sensing unit, a first control unit, and a light-emitting unit, wherein
the temperature sensing unit is configured to sense one of the temperature values at a corresponding one of the preset positions,
the first control unit is configured to convert the temperature value into a current value and to control the light-emitting unit to emit one of the first optical signals at a first luminous intensity corresponding to the current value,
the second temperature-to-optical signal conversion module comprises an optical signal receiving unit and a second control unit,
the optical signal receiving unit is configured to receive the plurality of second optical signals respectively corresponding to the preset positions within the server, and
the second control unit is configured to generate a first control instruction carrying a target rotational speed based on the plurality of second optical signals, and to transmit the first control instruction to the fan within the server, whereby the fan within the server responds to the first control instruction, parses the target rotational speed from the first control instruction, and rotates at the target rotational speed.

3. The fan speed control system based on optical signal transmission according to claim 2, wherein the first control unit and the second control unit are control chips.

4. The fan speed control system based on optical signal transmission according to claim 1, wherein each of the light-converging modules comprises a reflector or a refractor.

5. The fan speed control system based on optical signal transmission according to claim 4, wherein the reflector or the refractor of each of the light-converging modules is configured to reflect and converge a corresponding one of the first optical signals to form one of the second optical signals directed toward the second temperature-to-optical signal conversion module.

6. The fan speed control system based on optical signal transmission according to claim 1, wherein a position of each of the light-converging modules is determined based on a relative positional relationship between a corresponding one of the first temperature-to-optical signal conversion modules and the second temperature-to-optical signal conversion module.

7. The fan speed control system based on optical signal transmission according to claim 2, wherein the second control unit is configured to:
determine rotational speeds corresponding to second luminous intensities of the plurality of second optical signals;
determine a maximum rotational speed among the rotational speeds as the target rotational speed;
generate the first control instruction carrying the target rotational speed; and
transmit the first control instruction to the fan within the server.

8. The fan speed control system based on optical signal transmission according to claim 2, wherein the first control unit is further configured to, when the one of the temperature values exceeds a preset critical alarm threshold, control the light-emitting unit to emit a flashing third optical signal;
a corresponding one of the light-converging modules is further configured to reflect and converge the flashing third optical signal to form a flashing fourth optical signal directed toward the optical signal receiving unit;
the optical signal receiving unit is further configured to receive the flashing fourth optical signal;
the second control unit is further configured to, when a flashing duration of the flashing fourth optical signal reaches a preset flashing duration, generate a second control instruction carrying a preset maximum rotational speed, and transmit the second control instruction to the fan within the server, whereby the fan within the server responds to the second control instruction, parses the preset maximum rotational speed from the second control instruction, and rotates at the preset maximum rotational speed.

9. The fan speed control system based on optical signal transmission according to claim 8, wherein the first control unit is further configured to, when the one of the temperature values falls below a preset temperature hysteresis threshold, control the light-emitting unit to stop emitting the flashing third optical signal and to switch to emitting the one of the first optical signals.

10. A fan speed control method based on optical signal transmission, being applied to a first temperature-to-optical signal conversion module and comprising:
converting a temperature value at a preset position within a server into a current value; and
controlling a light-emitting unit to emit a first optical signal at a first luminous intensity corresponding to the current value, to cause a light-converging module to reflect and converge the first optical signal to form a second optical signal directed toward a second temperature-to-optical signal conversion module, wherein the second temperature-to-optical signal conversion module receives a plurality of second optical signals respectively corresponding to a plurality of preset positions within the server, and generates a first control instruction carrying a target rotational speed based on the plurality of second optical signals, and the first control instruction is configured to instruct a fan within the server to rotate at the target rotational speed.

11. The fan speed control method based on optical signal transmission according to claim 10, by further comprising:
controlling, when the temperature value exceeds a preset critical alarm threshold, the light-emitting unit to emit a flashing third optical signal, to cause the light-converging module to reflect and converge the flashing third optical signal to form a flashing fourth optical signal,
wherein the second temperature-to-optical signal conversion module, when a flashing duration of the flashing fourth optical signal reaches a preset flashing duration, generates a second control instruction carrying a preset maximum rotational speed and transmits the second control instruction to the fan within the server, and the second control instruction is configured to instruct the fan within the server to rotate at the preset maximum rotational speed.

12. The fan speed control method based on optical signal transmission according to claim 11, further comprising:
controlling, when the temperature value falls below a preset temperature hysteresis threshold, the light-emitting unit to stop emitting the flashing third optical signal and switch to emitting the first optical signal.

13. A fan speed control method based on optical signal transmission, being applied to a second temperature-to-optical signal conversion module and the fan speed control method comprising:
generating a first control instruction carrying a target rotational speed based on a plurality of second optical signals, wherein the second optical signals are formed by reflecting and converging first optical signals through light-converging modules, the first optical signals are obtained by first temperature-to-optical signal conversion modules through conversion of temperature values at preset positions within a server, and the light-converging modules are in one-to-one correspondence with the first temperature-to-optical signal conversion modules; and
transmitting the first control instruction to a fan within the server, wherein the first control instruction is configured to instruct the fan within the server to rotate at the target rotational speed.

14. The fan speed control method based on optical signal transmission according to claim 13, wherein the generating a first control instruction carrying a target rotational speed based on a plurality of second optical signals comprises:
determining rotational speeds corresponding to second luminous intensities of the plurality of second optical signals;
determining a maximum rotational speed among the rotational speeds as the target rotational speed; and
generating the first control instruction carrying the target rotational speed.

15. The fan speed control method based on optical signal transmission according to claim 13, further comprising:
generating, when a flashing duration of a flashing fourth optical signal reaches a preset flashing duration, a second control instruction carrying a preset maximum rotational speed, wherein the flashing fourth optical signal is formed by reflecting and converging a flashing third optical signal through a corresponding one of the light-converging modules, and the flashing third optical signal is emitted by one of the first temperature-to-optical signal conversion modules when a corresponding one of the temperature values exceeds a preset critical alarm threshold; and
transmitting the second control instruction to the fan within the server, wherein the second control instruction is configured to instruct the fan to rotate at the preset maximum rotational speed.

16.-17. (canceled)

18. A first temperature-to-optical signal conversion module, comprising a temperature sensing unit, a first memory, and one or more first processors, wherein the first memory stores computer-readable instructions that, when executed by the one or more first processors, cause the one or more first processors to perform steps of the fan speed control method based on optical signal transmission according to claim 10.

19. A second temperature-to-optical signal conversion module, comprising an optical signal receiving unit, a second memory, and one or more second processors, wherein the second memory stores computer-readable instructions that, when executed by the one or more second processors, cause the one or more second processors to perform steps of the fan speed control method based on optical signal transmission according to claim 13.

20. One or more non-transitory computer-readable storage media having computer-readable instructions stored therein, wherein the computer-readable instructions, when executed by one or more processors, cause the one or more processors to perform steps of the fan speed control method based on optical signal transmission according to claim 10.

21. One or more non-transitory computer-readable storage media having computer-readable instructions stored therein, wherein the computer-readable instructions, when executed by one or more processors, cause the one or more processors to perform steps of the fan speed control method based on optical signal transmission according to claim 13.

22. The fan speed control system based on optical signal transmission according to claim 2, wherein the temperature sensing unit is a temperature sensor, which is used for sensing one of the temperature values at a corresponding one of the preset positions in real time.
